(19) United States
(12) Patent Application Publication
(10) Pub. No.: US 2019/0368050 A1
(43) Pub. Date: Dec. 5, 2019

(54) COATING AND METHOD OF APPLYING A COATING FOR AN AEROFOIL OF A GAS TURBINE ENGINE

(71) Applicant: Siemens Aktiengesellschaft, Munich (DE)

(72) Inventor: Jonathan Wells, Welton, Lincoln (GB)

(73) Assignee: Siemens Aktiengesellschaft, Munich (DE)

(21) Appl. No.: 16/485,241

(22) PCT Filed: Jan. 10, 2018
(86) PCT No.: PCT/EP2018/050518

§ 371 Date: Aug. 12, 2019

(30) Foreign Application Priority Data
Feb. 21, 2017 (GB) 1702763.2

(51) Int. Cl. C23C 28/00; C23C 4/134; C23C 4/073; C23C 4/11; C23C 16/06; F01D 5/28

(52) U.S. Cl. CPC C23C 28/3215; C23C 4/134; C23C 4/073; C23C 4/11; F05D 2300/701; C23C 28/3455; F01D 5/288; F05D 2230/90; F05D 2300/175; C23C 16/06

(57) ABSTRACT

A component includes a nickel based alloy substrate having a coating system comprising a CrAl layer overlaying the nickel based alloy substrate, a NiCrAlY layer overlaying the CrAl layer and a yttria stabilized zirconia thermal barrier coating layer overlaying the NiCrAlY layer. A method of forming the coating system includes the steps air plasma spraying the NiCrAlY layer and air plasma spraying the yttria stabilized zirconia thermal barrier coating layer.

### CROSS REFERENCE TO RELATED APPLICATIONS

This application is the US National Stage of International Application No. PCT/EP2018/050518 filed Jan. 10, 2018, and claims the benefit thereof. The International Application claims the benefit of United Kingdom Application No. GB 1702763.2 filed Feb. 21, 2017. All of the applications are incorporated by reference herein in their entirety.

### FIELD OF INVENTION

The present invention relates to coatings for components that can be used in a gas turbine engine and in particularly but not exclusively air plasma sprayed thermal and corrosion resistant coatings on a turbine aerofoil.

### BACKGROUND OF INVENTION

Thermal barrier coating (TBC) systems use a thermal sprayed MCrAlY coating as a bond coat between the metal substrate of a component and a thermal-resistant ceramic outer coating. The MCrAlY coating has a minimum thickness required to give adequate oxidation life. However, the combined weight of the MCrAlY and the ceramic coating mean that this coating system can be critical to the life of certain components such as rotating blades. For certain gas turbine components such as rotating blades, the additional weight of this coating can lead to a reduced life cycle.

Thermal barrier coatings can also effect the aerodynamic performance of a rotor blade or stator vane stage by virtue of its thickness, which can reduce the available throat area between blades or vanes. This problem is particularly acute where the TBC is retrofitted and where the rotor blades or stator vanes are relatively small.

Conventional TBCs are based on 8 wt. % yttrium stabilized zirconia (YSZ), also known as partially stabilized YSZ. Above 1200° C. these 8 wt. % YSZ coatings are known to start to breaking down and therefore this limits the outer surface temperature capability. In addition, corrosive species can pull the yttrium out of the yttrium stabilized zirconia coating and subsequently destabilize it.

One known solution to improving adherence of TBC to a nickel based alloy component is to use PtAl or diffused platinum (Pt) bond coats between the component and the TBC. Whilst PtAl coatings used on any nickel based alloy diffused Pt bond coats can give improved lives, they are only effective on low Cr alloys i.e. Ni based alloys with less than 10% wt Cr. Both these coating systems are only effective with Electron Beam Physical Vapour Deposited (EBPVD) TBC systems. However, EBPVD TBC systems are known to experience problems in corrosive environments.

EP2024607B1 discloses a coating system for a gas turbine blade having different compositions in different locations on the blade. A first coating which can comprise Cr that can be diffused into the component applying known methods like chemical vapour deposition. Experiments have shown that good protection properties can be obtained if the first coating is a layer which is 5 to 25 [mu]m thick and/or comprises 15 to 30 weight-% Cr. A second coating can comprise MCrAlY, wherein M can be Co or Ni or a combination of both. Further elements such as Re, Si, Hf and/or Y can be included in the coating. An advantageous composition of the coating is 30 to 70 weight-% Ni, 30 to 50 weight-% Co, 15 to 25 weight-% Cr, 5 to 15 weight-% Al and up to 1 weight-% Y. Different thermal spray techniques such as vacuum plasma spraying (VPS), low pressure plasma spraying (LPPS), high velocity ox-fuel spraying (HVOF), cold gas spraying (CGS) or electroplating can be applied. The first coating is provided on the root of the blade and the second coating can be applied to any one of the neck, the outer surface of the airfoil and on at least a part of the platform.

EP2662529A1 discloses an airfoil comprising a coated surface section which is coated with a platinum-aluminide bond coating and a thermal barrier coating.

EP2032733A2 discloses a method of protecting a component, in particular a turbine blade, from the effects of hot corrosion includes the steps of (1) applying a chromium diffusion coating to the component and (2) applying a coating of a ceramic material to one or more selected regions of the chromium diffusion coating.

Therefore there is a desire to provide a lighter weight coating system that has sufficient thermal/oxidation resistance and corrosion protection and that sufficiently adheres to a component and one that advantageously contains a high-Cr content. In addition, it is desirable to provide a thinner coating systems which occupies less of the throat area between uncoated blades and vanes than conventional coatings.

### SUMMARY OF INVENTION

To address the problems of known coating systems there is provided a component for a gas turbine engine comprising a nickel based alloy substrate having a coating system comprising a CrAl layer overlaying the nickel based alloy substrate, a NiCrAlY layer overlaying the CrAl layer and a yttria stabilized zirconia thermal barrier coating layer.

Another aspect of the present coating system is a method of manufacturing the component comprising a nickel based alloy substrate having a coating system. The coating system comprising a CrAl layer overlaying the nickel based alloy substrate, a NiCrAlY layer overlaying the CrAl layer and a yttria stabilized zirconia thermal barrier coating layer, the method comprising the steps air plasma spraying the NiCrAlY layer and air plasma spraying the yttria stabilized zirconia thermal barrier coating layer.

The CrAl layer may have a thickness between and including 50-90 um.

The NiCrAlY layer may comprises 21-23% wt Cr, 9-11% wt Al, 0.8-1.2% wt Y, balance Ni.

The NiCrAlY layer may have a maximum thickness 35 um.

The NiCrAlY layer may comprise a surface roughness >10 um Ra.

The yttria stabilized zirconia thermal barrier coating layer is 50-500 um thick.

The yttria stabilized zirconia thermal barrier coating layer comprises a porosity 10-15%.

The coating system may be less than 7% of the total weight of the component and advantageously approximately 6% of the total weight of the component.

The component may be a rotor blade, one of an annular array of rotor blades, where a throat area is defined between adjacent rotor blades without a coating and wherein the throat area is less than 1000 mm².

The coating system may occupy less than 2.5%, advantageously approximately 1.5%, of the throat area.

The method of manufacturing the component may comprise the step of chemical vapour depositing the CrAl layer.

The method step of forming the CrAl layer may comprise the steps chemical vapour depositing a Cr layer and chemical vapour depositing an Al layer.

The method may comprise the step diffusing the component and coating system at a temperature in the range of 1080-1120° C. and for 1-4 hours.

### BRIEF DESCRIPTION OF THE DRAWINGS

The above mentioned attributes and other features and advantages of this invention and the manner of attaining them will become more apparent and the invention itself will be better understood by reference to the following description of embodiments of the invention taken in conjunction with the accompanying drawings, wherein

FIG. 1 shows part of a turbine engine in a sectional view and in which the present inventive transition duct is incorporated,

FIG. 2 shows a perspective view of a turbine blade having a coating system in accordance with the claimed subject matter,

FIG. 3 is a schematic section through an embodiment of the coating system,

FIG. 4 is a schematic section through another embodiment of the coating system.

### DETAILED DESCRIPTION OF INVENTION

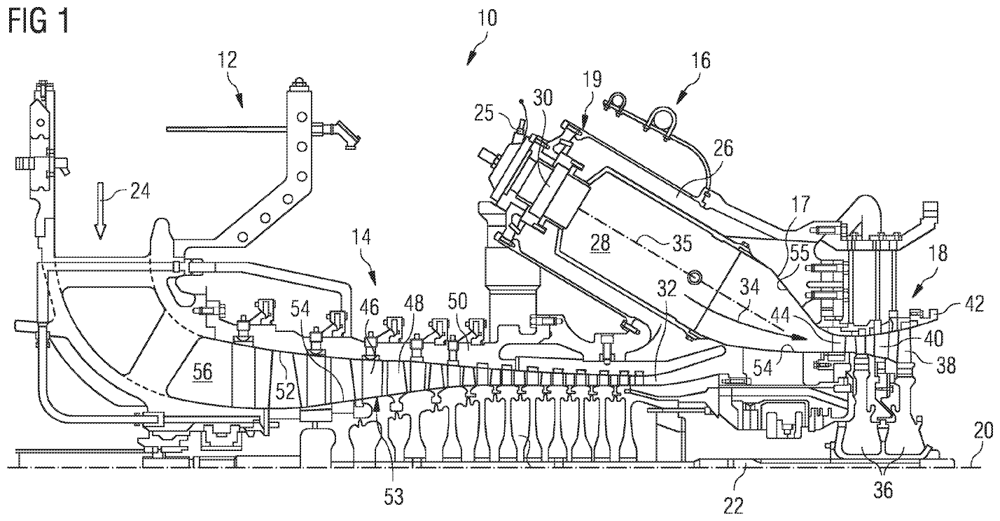

FIG. 1 shows an example of a gas turbine engine 10 in a sectional view. The gas turbine engine 10 comprises, in flow series, an inlet 12, a compressor section 14, a combustor section 16 and a turbine section 18 which are generally arranged in flow series and generally about and in the direction of a longitudinal or rotational axis 20. The gas turbine engine 10 further comprises a shaft 22 which is rotatable about the rotational axis 20 and which extends longitudinally through the gas turbine engine 10. The shaft 22 drivingly connects the turbine section 18 to the compressor section 14.

In operation of the gas turbine engine 10, air 24, which is taken in through the air inlet 12 is compressed by the compressor section 14 and delivered to the combustion section or burner section 16. The burner section 16 comprises a burner plenum 26, one or more combustion chambers 28 and at least one burner 30 fixed to each combustion chamber 28. The combustion chambers 28 and the burners 30 are located inside the burner plenum 26. The compressed air passing through the compressor 14 enters a diffuser 32 and is discharged from the diffuser 32 into the burner plenum 26 from where a portion of the air enters the burner 30 and is mixed with a gaseous or liquid fuel. The air/fuel mixture is then burned and the combustion gas 34 or working gas from the combustion is channeled through the combustion chamber 28 to the turbine section 18 via a transition duct 17.

This exemplary gas turbine engine 10 has a cannular combustor section arrangement 16, which is constituted by an annular array of combustor cans 19 each having the burner 30 and the combustion chamber 28, the transition duct 17 has a generally circular inlet that interfaces with the combustor chamber 28 and an outlet in the form of an annular segment. An annular array of transition duct outlets form an annulus for channeling the combustion gases to the turbine 18.

The turbine section 18 comprises a number of blade carrying discs 36 attached to the shaft 22. In the present example, two discs 36 each carry an annular array of turbine blades 38. However, the number of blade carrying discs could be different, i.e. only one disc or more than two discs. In addition, guiding vanes 40, which are fixed to a stator 42 of the gas turbine engine 10, are disposed between the stages of annular arrays of turbine blades 38. Between the exit of the combustion chamber 28 and the leading turbine blades 38 inlet guiding vanes 44 are provided and turn the flow of working gas onto the turbine blades 38.

The combustion gas from the combustion chamber 28 enters the turbine section 18 and drives the turbine blades 38 which in turn rotate the shaft 22. The guiding vanes 40, 44 serve to optimise the angle of the combustion or working gas on the turbine blades 38.

The turbine section 18 drives the compressor section 14. The compressor section 14 comprises an axial series of vane stages 46 and rotor blade stages 48. The rotor blade stages 48 comprise a rotor disc supporting an annular array of blades. The compressor section 14 also comprises a casing 50 that surrounds the rotor stages and supports the vane stages 46. The guide vane stages include an annular array of radially extending vanes that are mounted to the casing 50. The vanes are provided to present gas flow at an optimal angle for the blades at a given engine operational point. Some of the guide vane stages have variable vanes, where the angle of the vanes, about their own longitudinal axis, can be adjusted for angle according to air flow characteristics that can occur at different engine operations conditions.

The casing 50 defines a radially outer surface 52 of the passage 56 of the compressor 14. A radially inner surface 54 of the passage 56 is at least partly defined by a rotor drum 53 of the rotor which is partly defined by the annular array of blades 48.

The present invention is described with reference to the above exemplary turbine engine having a single shaft or spool connecting a single, multi-stage compressor and a single, one or more stage turbine. However, it should be appreciated that the present invention is equally applicable to two or three shaft engines and which can be used for industrial, aero or marine applications.

The terms upstream and downstream refer to the flow direction of the airflow and/or working gas flow through the engine unless otherwise stated. The terms forward and rearward refer to the general flow of gas through the engine. The terms axial, radial and circumferential are made with reference to the rotational axis 20 of the engine.

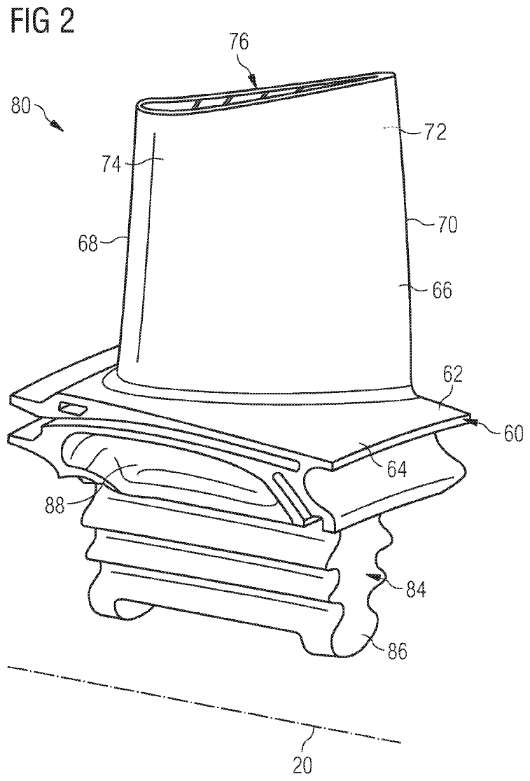

FIG. 2 shows a turbine blade 80 which is coated with the present coating system 100. The turbine blade 80 is similar to the blades 38, 48 described above and could be implemented in the gas turbine engine 10. The turbine blade 80 has a root portion 84 comprising a root fixture 86 and a neck 88. The neck 88 may be optional on other blades. The root fixture 86 is a fir-tree root configuration, but in other embodiments other well known fixtures can be implemented. The root fixture 86 engages with a complimentary fixture formed by one or more rotor discs. The neck 88 blends into a platform 60 which has a radially inner surface 64 and a radially outer surface 62 or gas washed surface 62. Extending from the platform 60 is an aerofoil 66 comprising a leading edge 68 and a tailing edge 70. A generally concave pressure surface 72 and a generally convex suction surface 74 each extend between the leading and trailing edges 68, 70. The aerofoil's 66 pressure and suction surfaces 72, 74 also extend in a radial direction from the platform 60 to a tip 76 of the aerofoil 66. The blade 80 shown here is an unshrouded blade, but in other examples the blade 80 could be a shrouded blade or a blade having one or more winglets as known in the art.

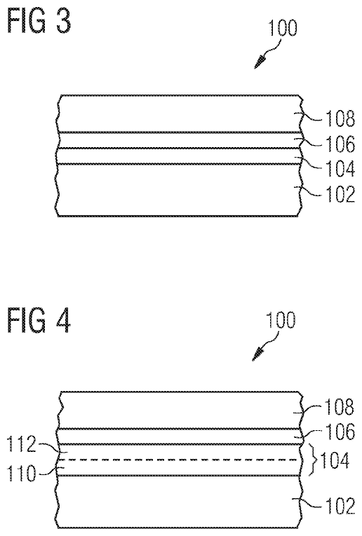

FIG. 3 is a schematic section through an embodiment of the coating system 100. The coating system 100 is coated over surfaces of the turbine blade 80. The turbine blade 80 is cast, but could be made from additive manufacturing methods. The turbine blade 80 comprises a nickel based alloy and such nickel based alloy compositions are well known in the art. The term ‘substrate’ is used to denote the turbine blade material. The coating system 100 is applied to all gas washed surfaces on the blade 80 and similarly on other components such as the static vanes. Gas washed surfaces include the aerofoil's pressure and suction surfaces 72, 74, the platform's surface 62 and even the surface of the tip 76. Where there is a winglet or shroud or even a further platform in the case of a vane, the gas washed surface of the further platform can also be coated. A ‘gas washed’ surface is intended to mean a surface or part of a surface where the hot working gas flow through the engine is in contact with the surface. Thus the substrate (denoted by 102) could be part of a component wall on to which the coating system 100 is applied. The component could be any one of a blade, a vane, a liner of a combustor, a transition duct or even an exhaust nozzle.

The coating system 100 applied to the nickel based alloy substrate 102 is a chromium-aluminide (CrAl) layer 104 overlaying the nickel based alloy substrate 102, then a nickel-chromium-aluminium-yttria (NiCrAlY) layer 106 overlaying the CrAl layer and then over the NiCrAlY layer 106 is a yttria-stabilized-zirconia (YSZ) thermal barrier coating layer 108. Importantly, in the method of forming the coating system 100, the NiCrAlY layer 106 and the yttria stabilized zirconia thermal barrier coating layer 108 are each applied by separate air plasma spraying steps. The CrAl layer 104 is applied using a chemical vapour depositing technique.

In a further embodiment of the coating system 100 and as shown in FIG. 4, the method of forming the coating system involves forming the CrAl layer 104 by the by a two step process where a Cr layer 110 is deposited by a chemical vapour deposition step and then a layer of Al is deposited by a chemical vapour depositing step. The Cr readily diffuses into the Ni alloy substrate and then once the Al is applied it forms a NiAl phase with limited Cr solubility. Thus a single layer comprising both chromium and aluminium may be formed.

Importantly, by which ever method forms the CrAl layer 104, its thickness is between and including 50-90 μm thick. The NiCrAlY layer 106 is approximately 22 μm thick, but it could be between 5-35 μm thick. The yttria stabilized zirconia thermal barrier coating layer 108 is approximately 200 μm thick, but it can be between 50-500 μm thick. Typically the coating system 100 can weigh approximately 25% less than the conventional coating and can be between 20 and 30% lighter.

The NiCrAlY layer 106 comprises 16-23% wt Cr, 9-11% wt Al, 0.8-1.2% wt Y with the balance Ni. The NiCrAlY layer 106 has a thickness of 5-35 μm. The NiCrAlY layer 106 comprises a surface roughness >10 μm and <35 μm Ra. The roughness is controlled by the particle size of the spray powder used in the Air Plasma Spraying although other factors can influence surface roughness. The NiCrAlY layer 106 is applied by Air Plasma Spraying.

The yttria-stabilized-zirconia thermal barrier coating layer 108 comprises a porosity 10-15%. The yttria-stabilised zirconia thermal barrier coating layer 108 is applied by Air Plasma Spraying. The life of an air plasma sprayed TBC is dependent on spraying parameters such as how hot the powder particles are and also porosity. In general, if the coating is too dense significant stresses build up at the interface and the coating spalls and if the coating is too porous it can be prone to erosion damage or prone to cracks linking between pores. It has been found that a porosity of between 10-15% is advantageous.

To complete the manufacture of the coating system 100, the component 50, after application of all layers of the coating system have been applied are diffused together at a temperature in the range of 1080-1120° C. for 1-4 hours. The exact temperature and exact time is dependent on the composition of the nickel based superalloy used.

The present coating system 100 is particularly applicable to relatively small rotating gas turbine blades where the weight of the coating system is significant. In the turbine of the gas turbine engine, the blades are rotating at high-speed and therefore incur high centrifugal forces. These high centrifugal forces and the ‘mechanical stresses’ induced in the blade are one of the factors that limit the life of blades. For a relatively small blade a conventional ‘thick’ coating system can significantly add to the overall weight of the blade and reduce the life of the blade due to increased mechanical stresses. Advantageously, the coating system 100 is less than 7% of the total weight of the blade. In one example the coating system is 6% of the total weight of each blade. Conventional coatings systems on the same relatively small blade are typically at least 8% of the total weight of the blade. For blades that are life critical such a small saving in weight can lead to a significant increase in the life of the blade.

In addition to the present coating system being relatively light-weight, it is also thinner than conventional TBC systems. This can be advantageous because the coating system 100 does not reduce a throat area between circumferentially adjacent blades of a rotor. The throat area is the minimum area between adjacent blades or vanes through which the working gas flows. A relatively thick TBC applied to relatively small blades of a rotor assembly could have a small but significant impact on the efficiency of the rotor assembly. Thus for a rotor assembly having relatively small blades and the throat area between two adjacent blades is less than 1000 mm², the present coating system 100 is particularly suitable. Advantageously, when applied to relatively small blades and vanes, the coating system 100 can be less than 2.5% of the throat area of an uncoated blade. In one example, a rotor blade stage has an average throat area of approximately 700 mm² and application of the coating system 100 occupies approximately 1.5% of the throat area. A conventional coating typically occupies approximately 3.5% of the throat area. Thus it should be appreciated that the present coating system 100 can provide a significant efficiency improvement over conventional coating systems.

1. A component for a gas turbine engine comprising a nickel based alloy substrate having a coating system comprising:
a CrAl layer overlaying the nickel based alloy substrate,
a NiCrAlY layer overlaying the CrAl layer, and
a yttria stabilized zirconia thermal barrier coating layer.

2. The component as claimed in claim 1, wherein the CrAl layer is between and including 50-90 um thick.

3. The component as claimed in claim 1, wherein the NiCrAlY layer comprises 21-23% wt Cr, 9-11% wt Al, 0.8-1.2% wt Y, balance Ni.

4. The component as claimed in claim 1, wherein the NiCrAlY layer has a thickness between 5-35 μm.

5. The component as claimed in claim 1, wherein the NiCrAlY layer comprises a minimum surface roughness of 10 μm Ra.

6. The component as claimed in claim 1,
wherein the yttria stabilized zirconia thermal barrier coating layer is 50-500 μm thick.

7. The component as claimed in claim 1,
wherein the yttria stabilized zirconia thermal barrier coating layer comprises a porosity 10-15%.

8. The component as claimed in claim 1,
wherein the coating system is less than 7% of the total weight of the component.

9. The component as claimed in claim 1, wherein the component is a rotor blade, one of an annular array of rotor blades, wherein a throat area is defined between adjacent rotor blades without a coating and wherein the throat area is less than 1000 mm2.

10. The component as claimed in claim 9,
wherein the coating system occupies less than 2.5% of the throat area.

11. A method of manufacturing a component comprising a nickel based alloy substrate having a coating system, the coating system comprising a CrAl layer overlaying the nickel based alloy substrate, a NiCrAlY layer overlaying the CrAl layer and a yttria stabilized zirconia thermal barrier coating layer, the method comprising:
air plasma spraying the NiCrAlY layer, and
air plasma spraying the yttria stabilized zirconia thermal barrier coating layer.

12. The method of manufacturing a component as claimed in claim 11, the method further comprising:
chemical vapour depositing the CrAl layer.

13. The method of manufacturing a component as claimed in claim 11, wherein the CrAl layer is formed by the method comprising the steps
chemical vapour depositing a Cr layer, and
chemical vapour depositing an Al layer.

14. The method of manufacturing a component as claimed in claim 11, the method further comprising:
diffusing the component and coating system at a temperature in the range of 1080-1120° C. and for 1-4 hours.

15. The component as claimed in claim 8,
wherein the coating system is approximately 6% of the total weight of the component.

16. The component as claimed in claim 10,
wherein the coating system occupies approximately 1.5% of the throat area.
